(19) United States
(12) Patent Application Publication
(10) Pub. No.: US 2008/0137278 A1
(43) Pub. Date: Jun. 12, 2008

(54) Memory chip and insert card having the same thereon

(75) Inventor: Ching-Shui Chih, Jhonghe City (TW)

Correspondence Address: KAMRATH & ASSOCIATES P.A., 4825 OLSON MEMORIAL HIGHWAY, SUITE 245, GOLDEN VALLEY, MN, 55422, US

(73) Assignee: KRETON CORPORATION, Jhonghe City (TW)

(21) Appl. No.: 11/653,640

(22) Filed: Jan. 16, 2007

(30) Foreign Application Priority Data
Dec. 11, 2006 (TW) 095146193

(51) Int. Cl. H05K 7/00; H01L 23/49

(52) U.S. Cl. 361/684; 257/784; 257/E23.024

(57) ABSTRACT

A memory chip has a substrate, a die and an encapsulant. The substrate has multiple edges, a top surface, multiple die contacts, multiple outer contacts and multiple jumper contacts. The multiple die contacts are formed on the top surface of the substrate. The multiple outer contacts are formed on the edges of the substrate, and parts of the output contacts are electronically connected to parts of the die contacts directly. The multiple jumper contacts are formed on the top surface of the substrate and are electronically connected to the die contacts and outer contacts that are not connected together. The die is mounted on the substrate and electronically connects to the die contacts through bonding wires. The encapsulant is formed on the top surface of the substrate, entirely covers and protects the die contacts, the jumper contacts and the die.

### BACKGROUND OF THE INVENTION

1. Field of the Invention

The present invention relates to a memory chip and an insert card, and more particularly to a memory chip that can be controlled to change operating modes and an insert card having the memory chip thereon.

2. Description of Related Art

Computers are commonly used recently. The performance of the computers is based on hardwares in the computers, especially the insert cards such as memory, Video Graphics Array (VGA) card or the like.

A conventional method to manufacture an insert card comprises steps of packaging memory chips and mounting the memory chips on a motherboard. The step of packaging memory chip comprises packaging multiple dies respectively to become multiple memory chips by quad flat package (QFP), small outline package (SOP), bump grid array (BGA) package or the like. The step of mounting the memory chips on a motherboard comprises installing the memory chips on a motherboard with welding points between the memory chips and the motherboard by surface mount technology (SMT).

The advancement of semiconductor technology has resulted in memory chips being smaller. Thus more memory chips can be mounted on the motherboard to increase performance of the insert card.

However, small size memory chips are difficult to be installed and removed from the motherboard, especially when the welding points are located between the memory chips and the motherboard.

To overcome the shortcomings, the present invention provides a memory chip and an insert card having the same thereon to mitigate or obviate the aforementioned problems.

### SUMMARY OF THE INVENTION

The main objective of the invention is to provide a memory chip and an insert card having the same thereon.

A memory chip in accordance with the present invention comprises a substrate, a die and an encapsulant. The substrate has multiple edges, a top surface, multiple die contacts, multiple outer contacts and multiple jumper contacts. The multiple die contacts are formed on the top surface of the substrate. The multiple outer contacts are formed on the edges of the substrate, and parts of the output contacts are electronically connected to parts of the die contacts directly. The multiple jumper contacts are formed on the top surface of the substrate and are electronically connected to the remaining die contacts and outer contacts. The die is mounted on the substrate and electronically connects to the die contacts through bonding wires. The encapsulant is formed on the top surface of the substrate, entirely covers and protects the die contacts, the jumper contacts and the die.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a first embodiment of a memory chip in accordance with the present invention without an encapsulant;

FIG. 2 is a top view of the memory chip in FIG. 1;

FIG. 3 is a side view in partial section of the memory chip in FIG. 1 that has the encapsulant;

FIG. 4 is an exploded perspective view of a first embodiment of an insert card with multiple memory chips in FIG. 3; and

FIG. 5 is a perspective view of a second embodiment an insert card with a memory chip in FIG. 3.

### DETAILED DESCRIPTION OF PREFERRED EMBODIMENT

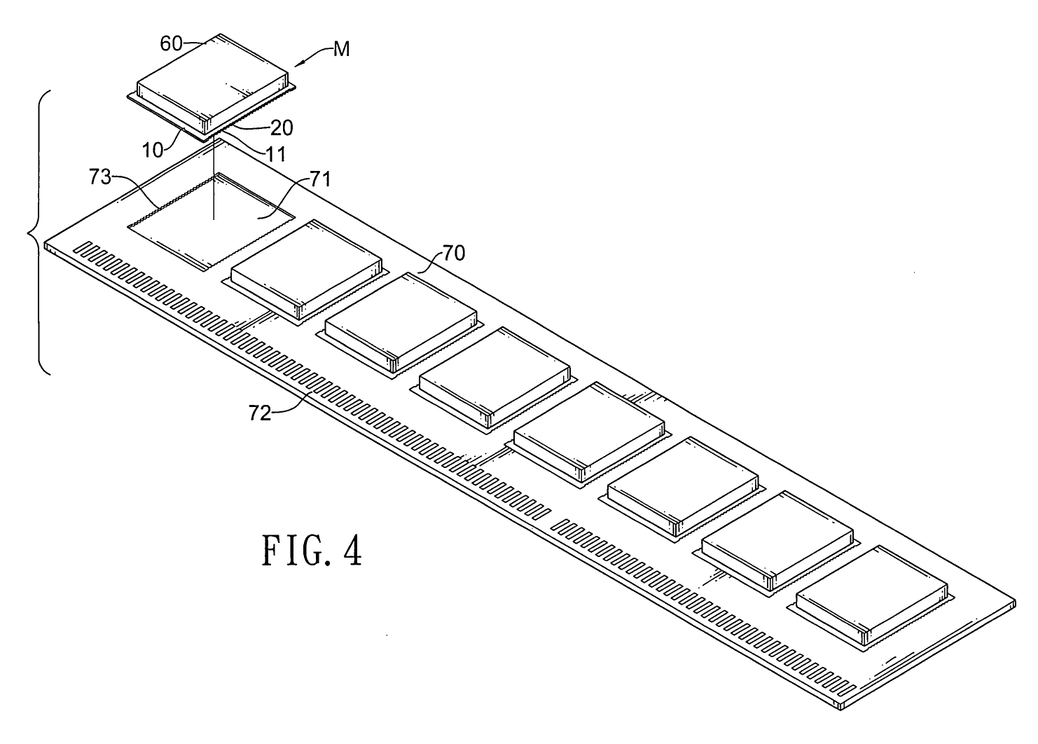

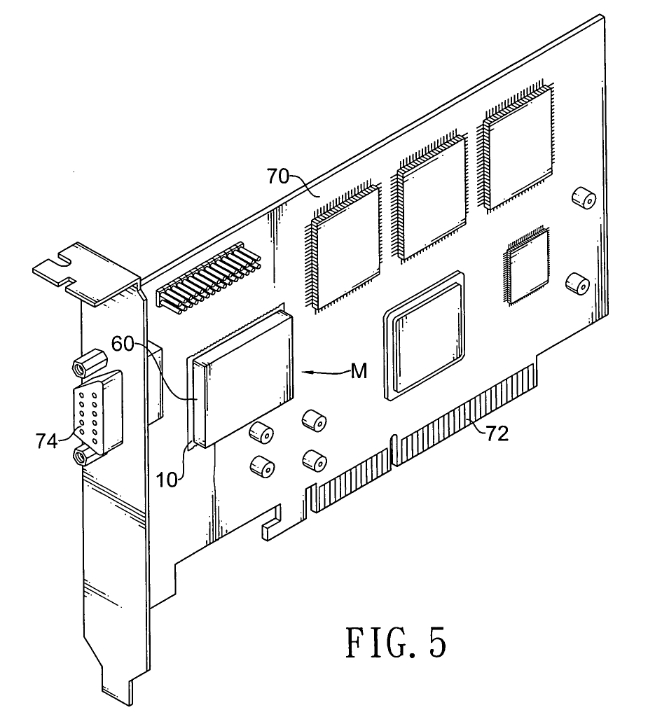

With reference to FIGS. 4 and 5, an insert card in accordance with the present invention may be a memory, a video graphics array (VGA) card or the like and comprises a motherboard (70) and at least one memory chip (M).

The motherboard (70) has a front surface, a rear surface, at least one chip region (71), multiple plugs (72), multiple chip contacts (73) and an optional connector (74).

The front surface of the motherboard (70) has two horizontal edges and two vertical edges.

The rear surface of the motherboard (70) has two horizontal edges.

The at least one chip region (71) has multiple edges and may be formed on the top or the rear surface of the motherboard (70). Furthermore, if the motherboard (70) has multiple chip regions (71), the chip regions (71) may be formed on both surfaces of the motherboard (70).

The plugs (72) are formed on the corresponding horizontal edges of the two surfaces on the motherboard (70).

The chip contacts (73) are formed on the edges of the at least one chip region (71).

The connector (74) is mounted on one of the vertical edges of the front surface of the motherboard (70) if the insert card is a VGA card.

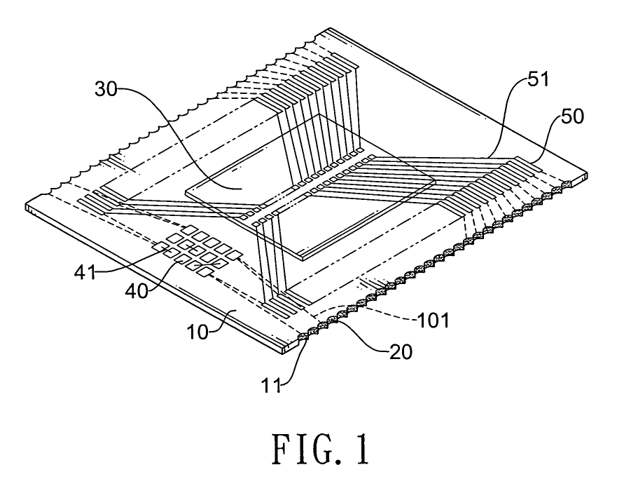

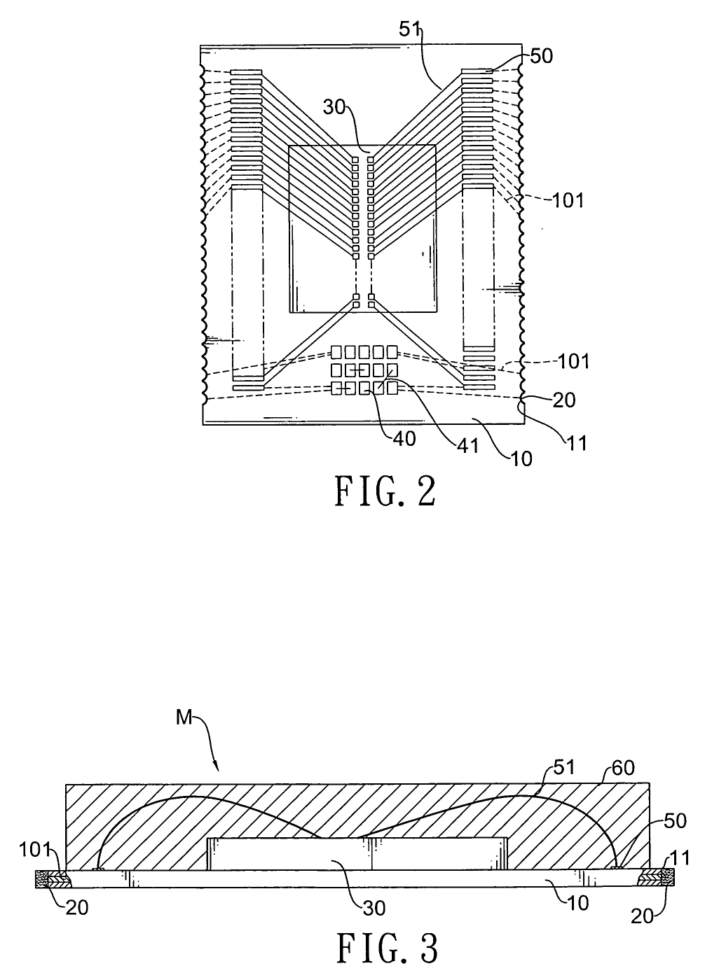

With reference to FIGS. 1-3, the memory chip (M) is mounted in the chip region (71) by surface mount technology (SMT) and comprises a substrate (10), a die (30) and an encapsulant (60).

The substrate (10) has multiple edges, a top surface, multiple die contacts (50), multiple outer contacts (20), multiple jumper contacts (40) and multiple optional jumpers (41) and may comprise patterned circuits (101) and multiple indentations (11).

The edges may comprise two long edges and two short edges.

The die contacts (50) are formed on the top surface of the substrate (10) and.

The outer contacts (20) are formed on the edges of the substrate (10). Furthermore, the outer contacts (20) correspond to and are connected respectively to the chip contacts (73) on the motherboard (70) by SMT. Parts of the outer contacts (20) are electronically connected to parts of the die contacts (50) directly.

The jumper contacts (40) are formed on the top surface of the substrate (10) and are electronically connected to the die contacts (50) and outer contacts (20) those are kept free from connecting with each other.

Each jumper (41) connects two of the jumper contacts (40) to change the connections between the die contacts (50) and the outer contacts (20). Different connections between the die contacts (50) and the outer contacts (20) relate to different operating mode of the memory chip (M), such as full-bit operating mode, half-size operating mode or the like.

The patterned circuits (101) are formed inside the substrate (10) and are used to electronically connect the die contacts (50), outer contacts (20) and jumper contacts (40).

The indentations (11) are formed on the long edges of the substrate (10) for forming the outer contacts (20) thereon.

The die (30) is mounted on the substrate (10) and electronically connects to the die contacts (50) through bonding wires (51), and the die contacts (50) are arranged beside the die (30).

The encapsulant (60) is formed on the top surface of the substrate (10), entirely covers and protects the die contacts (50), the jumper contacts (40) and the die (30).

The described memory chip (M) is easy to be installed on and dismounted from the motherboard (70) because the welding points are on the edges of the memory chip (M), and further, the manufacturing cost and the thickness of the memory chip (M) also reduce because of the same reason. In addition, the jumper contacts (40) provide a feature that people can easily change the operating mode of the memory chip (M) by using jumpers (41).

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A memory chip comprising:
a substrate having
multiple edges;
a top surface;
multiple die contacts being formed on the top surface of the substrate;
multiple outer contacts being formed on the edges of the substrate, and parts of the output contacts being electronically connected to parts of the die contacts directly; and
multiple jumper contacts being formed on the top surface of the substrate and being electronically connected to the die contacts and outer contacts those are kept free from connecting with each other;
a die being mounted on the substrate and electronically connecting to the die contacts through bonding wires; and
an encapsulant being formed on the top surface of the substrate, entirely covering and protecting the die contacts, the jumper contacts and the die.

2. The memory chip as claimed in claim 1, wherein the substrate further comprises patterned circuits being formed inside the substrate to electronically connect the die contacts, outer contacts and jumper contacts.

3. The memory chip as claimed in claim 1, wherein
the edges of the substrate comprise two long edges and two short edges; and
the substrate further comprises multiple indentations being formed on the long edges of the substrate for forming the output contacts thereon.

4. The memory chip as claimed in claim 1, wherein the die contacts are arranged beside the die.

5. The memory chip as claimed in claim 1, wherein the substrate further has multiple jumpers, and each jumper connects two of the jumper contacts to change the connections between the die contacts and the outer contacts.

6. An insert card having at least one memory chip as claimed in claim 1, wherein the insert card comprises
a motherboard having
two surfaces, and each surface having two horizontal edges and two vertical edges;
at least one chip region having multiple edges and being formed on the surface of the motherboard for containing the memory chip;
multiple plugs being formed on corresponding horizontal edges of the surfaces of the motherboard; and
multiple chip contacts being formed on the edges of the at least one chip region, corresponding to and being electronically connected to the outer contacts on the substrate of the at least one memory chip by surface mount technology.

7. The insert card as claimed in claim 6 being a memory.

8. The insert card as claimed in claim 6 being a video graphics array card.

9. The insert card as claimed in claim 6, wherein the substrate of each one of the at least one memory chip further comprises patterned circuits being formed inside the substrate to electronically connect the die contacts, outer contacts and jumper contacts.

10. The insert card as claimed in claim 6, wherein
the edges of the substrate of each one of the at least one memory chip comprise two long edges and two short edges; and
the substrate of each one of the at least one memory chip further comprises multiple indentations being formed on the long edges of the substrate for forming the output contacts thereon.

11. The insert card as claimed in claim 6, wherein the die contacts of each one of the at least one memory chip are arranged beside the die of the memory chip.

12. The insert card as claimed in claim 6, wherein the substrate of each one of the at least one memory chip further has multiple jumpers, and each jumper connects two jumper contacts to change the connections between the die contacts and the outer contacts of the memory chip.

13. The insert card as claimed in claim 7, wherein the insert card has multiple memory chips and multiple chip regions formed on both the surfaces of the motherboard.

14. The insert card as claimed in claim 8, wherein the motherboard further comprises a connector being mounted on one of the vertical edges on one of the surfaces of the motherboard.
